(19) United States
(12) Patent Application Publication
(10) Pub. No.: US 2023/0189548 A1
(43) Pub. Date: Jun. 15, 2023

(54) DISPLAY APPARATUS

(71) Applicant: LG DISPLAY CO., LTD., SEOUL (KR)

(72) Inventors: Chanhyeok PARK, Paju-si (KR); Heeseok NOH, Gimpo-si (KR)

(73) Assignee: LG DISPLAY CO., LTD., SEOUL (KR)

(21) Appl. No.: 17/897,479

(22) Filed: Aug. 29, 2022

(30) Foreign Application Priority Data
Dec. 13, 2021 (KR) 10-2021-0177848

(51) Int. Cl. H01L 51/52

(52) U.S. Cl. CPC H01L 51/5237; H01L 51/529; H01L 51/5284

(57) ABSTRACT

A display apparatus for improving heat-dissipation performance, impact absorption performance, and rigidity while reducing a non-display area, a discharge function can be performed by connecting a cover member to a side surface of the porous member via a discharging member, and metal powders or an organic material are disposed on a side surface of the porous member, thereby improving the rigidity, impact absorption and discharge performance of the porous member.

### CROSS-REFERENCE TO RELATED APPLICATION

This application claims the priority of Korean Patent Application No. 10-2021-0177848 filed on Dec. 13, 2021, which is hereby incorporated by reference in its entirety.

### BACKGROUND

### Field of the Disclosure

The present disclosure relates to a display apparatus, and more specifically, to a display apparatus for improving heat-dissipation performance, impact absorption performance, and rigidity with keeping a simplified a structure.

### Description of the Background

Various schemes and forms are used for display apparatuses that display images on TVs, monitors, smart phones, tablet PCs, and laptops.

Among the display apparatuses, a liquid crystal display apparatus (LCD) has been used up to now. Use and application of an organic light-emitting display apparatus (OLED) subsequent thereto are expanding.

The display apparatus includes a liquid crystal or a light-emitting element to implement an image. The display apparatus includes a thin-film transistor to individually control an operation of each liquid crystal or light-emitting element such that an image can be displayed on a substrate.

For example, the organic light-emitting display apparatus includes a thin-film transistor for driving a pixel and a light-emitting element that generates light upon receiving a signal from the thin-film transistor.

Further, the organic light-emitting display apparatus requires various additional components such as a driving integrated circuit and a printed circuit board in addition to a display panel to display the image.

The additional components may be located in a non-display area of the organic light-emitting display apparatus or connected to a flexible circuit board.

The non-display area of the organic light-emitting display apparatus may be a bezel area. When the non-display area increases, an overall size of the product increases. This reduces portability and also causes a disadvantage in design. Further, when the non-display area is enlarged, a user's gaze is dispersed, such that immersion in a screen can be reduced.

In the organic light-emitting display apparatus applied to a portable electronic device, a lot of impact may occur when the user carries the device or when assembling a product.

Additional components such as a driving integrated circuit or the printed circuit board that is configured to display an image of the display apparatus may be connected to a pad portion of the display panel or the flexible circuit board and may be disposed under the display panel.

In order to place the additional parts under the display panel, the display panel or the flexible circuit board needs to be bent. The larger a bending radius thereof, the larger the display apparatus.

As the radius of curvature increases, the flexible circuit board or the display panel may be bent more stably and easily. However, as the radius of curvature increases, the non-display area increases and the size of the display apparatus inevitably increases.

Moreover, in the organic light-emitting display apparatus applied to a portable electronic device, a lot of impact may occur when the user carries the device or when assembling a product. Thus, the display apparatus may require additional components to improve shock absorption and heat dissipation.

For example, a cushion plate for absorbing impact and performing a heat-dissipation function may be disposed under the display panel. The cushion plate may be formed by stacking a plurality of layers having various functions, such as a heat-dissipation layer with a heat-dissipation function, a cushion layer that may absorb impact, and an adhesive layer that combines the heat-dissipation layer and the cushion layer to each other.

The thicker each of the heat-dissipation layer and the cushion layer, the greater each of the heat-dissipation function and the impact absorption function. A total thickness of the display apparatus may increase by an amount by which a total of the thicknesses of these functional layers increases. As the radius of curvature of the bending portion or the flexible circuit board increases, a size of the non-display area increases.

When the thickness of each of the heat-dissipation layer and the cushion layer is smaller to reduce the overall thickness of the display apparatus, the heat-dissipation function and the impact absorption function are reduced, thereby increasing a possibility of damage to the display apparatus.

For example, when the display apparatus is mounted on or is removed from a manufacturing apparatus in a process of manufacturing the display apparatus, a strong impact may be applied to a side surface of the display apparatus. Further, when a product drops down while using the same, a strong impact may be applied to the side surface of the display apparatus, so that a side area of the display apparatus is highly likely to be damaged.

Moreover, the display apparatus may include a cover member made of glass or plastic material to protect a display panel from an external impact. However, an electric charge generated due to friction between the cover member and an external object or the electric charge generated from an outside is accumulated on the cover member. Thus, electric field may be generated in proportion to the accumulated charge.

The electric charge or electric field generated in the display apparatus may move to a distal end or a side surface of the display panel. Thus, a phenomenon in which a threshold voltage of a driving thin-film transistor disposed at the side surface of the display panel has been shifted may occur.

The shift of the threshold voltage of the driving thin-film transistor may cause the distal end or the side area of the display panel to emit light more brightly than other areas, or may cause a greenish phenomenon, thereby lowering display quality.

The above information disclosed in this Background section is only for enhancement of understanding of the background of the described technology and therefore it may contain information that does not form prior art that is already known to a person of ordinary skill in the art.

### SUMMARY

Accordingly, the present disclosure is directed to a display apparatus that substantially obviates one or more of problems due to limitations and disadvantages described above.

More specifically, the present disclosure is to improve impact absorption, rigidity and heat-dissipation function while reducing a thickness and a width of the display apparatus.

Further, the present disclosure is to reduce a phenomenon in which the distal end of the display panel emits light more brightly than other areas, or a greenish phenomenon, thereby improving display quality.

The present disclosure is not limited to the above-mentioned features. Other advantages of the present disclosure that are not mentioned may be understood based on following descriptions, and may be more clearly understood based on aspects of the present disclosure. Further, it will be easily understood that the purposes and advantages of the present disclosure may be realized using means shown in the claims and combinations thereof.

A display apparatus according to an aspect of the present disclosure includes a display panel for displaying an image; a cover member disposed on a upper surface of the display panel and protecting the display panel from external impact; and a porous member disposed under the display panel, wherein metal powders may be disposed on a side area of the porous member.

Moreover, the porous member includes a conductive metal, and a plurality of pores located inside the conductive metal, and an organic material may be disposed in at least some of the plurality of pores.

A display apparatus according to another aspect of the present disclosure includes a display panel for displaying an image; a cover member disposed on a upper surface of the display panel and protecting the display panel from external impact; a porous member disposed under the display panel and having a conductive metal and a plurality of pores located inside the conductive metal; and a conductive member disposed on a upper surface or a lower surface of the porous member, wherein an organic material may be disposed in the plurality of pores of the porous member.

Moreover, the conductive member may include metal powders or a metal plate.

The specific details of other aspects are included in the detailed description and drawings.

The display apparatus according to an aspect of the present disclosure may include the porous member having all the heat-dissipation function, the cushion function, and the electrical conducting function. Thus, the display apparatus may have effective cushion, discharge and heat-dissipation functions only using the porous member without adding a separate heat-dissipation layer or cushion layer thereto.

According to an aspect of the present disclosure, since the porous member has excellent heat-dissipation function and cushion function even at a small thickness thereof, the overall thickness of the cushion plate may be greatly reduced, so that the overall thickness of the display apparatus and the size of the non-display area may be reduced.

According to an aspect of the present disclosure, disposing the metal powders on the side area of the porous member may allow the side surface of the porous member may be reinforced, so that the display apparatus may be protected from impact applied to the side surface of the display apparatus.

According to an aspect of the present disclosure, connecting the cover member and the porous member to each other via the discharging member may allow the electric charge or electric field transferred to the side surface of the display panel to be discharged to the porous member.

Effects of the present disclosure are not limited to the above-mentioned effects, and other effects as not mentioned will be clearly understood by those skilled in the art from following descriptions.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1A is a plan view showing a front surface of the display apparatus according to an aspect of the present disclosure;

FIG. 1B is a plan view showing a back surface of the display apparatus;

FIG. 2 is a cross-sectional view taken along I-I′ in FIG. 1A;

FIG. 3A is an enlarged view of A area of FIG. 2;

FIG. 3B is a microscopic image of a portion of a porous member of FIG. 3A;

FIG. 4 is a cross-sectional view taken along II-II′ of FIG. 1B;

FIG. 5A to FIG. 5D are cross-sectional views showing a porous member on which metal powders are disposed according to an aspect of the present disclosure; and

FIG. 6A to FIG. 6B are cross-sectional views showing a porous member on which a conductive member is disposed according to an aspect of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed below, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the aspects of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The display apparatus according to the present disclosure may be applied to an organic light-emitting display apparatus, but is not limited thereto, and may be applied to various display apparatuses such as an LED display apparatus or a quantum dot display apparatus.

Hereinafter, a configuration of a display apparatus according to an aspect of the present disclosure will be described.

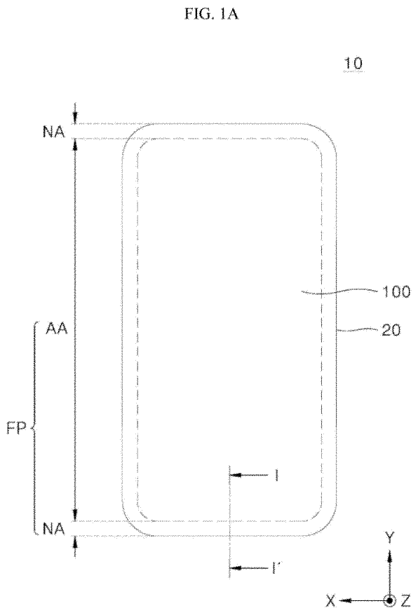

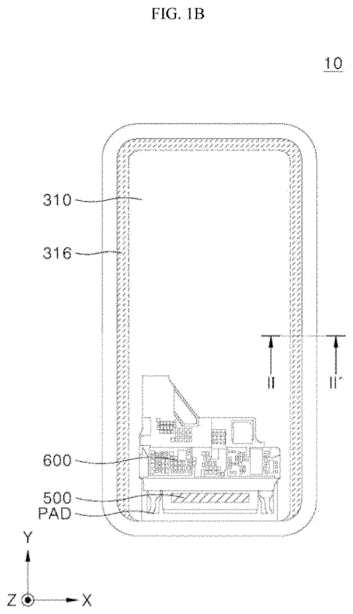

FIG. 1A is a plan view showing a front surface of a display apparatus according to an aspect of the present disclosure, and FIG. 1B is a plan view showing a back surface of the display apparatus.

As used herein, each of frontward and upward directions may mean a Z-axis direction, and each of backward and downward directions may mean a −Z-axis direction. Moreover, an upper side, a lower side, a left side, and a right side are related to a plan view (defined by an X-axis direction and a Y-axis direction) of the display apparatus or a display panel.

The display apparatus 10 may include a cover member 20, a display panel 100 coupled to a back surface of the cover member 20, and a frame disposed on the back surface of the display panel 100 so as to support the cover member 20. The display panel 100 may be disposed between the cover member 20 and the frame (not shown).

The cover member 20 may be disposed to cover the front surface of the display panel 100, and may protect the display panel 100 from the external impact.

An edge portion of the cover member 20 may have a rounded shape formed to be curved toward the back surface thereof (−Z axis direction) on which the display panel 100 is disposed.

In this case, the cover member 20 is disposed to cover at least a partial area of a side surface of the display panel 100, thereby protecting not only the front surface of the display panel 100 but also the side surface thereof from the external impact.

The image displayed on the display panel 100 may be displayed through a front surface of the cover member 20. Since the cover member 20 overlaps with the display area AA that displays an image, the cover member may be made of a transparent material such as cover glass so that the image may be displayed therethrough. For example, the cover member 20 may be made of one of a transparent plastic material, a glass material and a tempered glass material. The present disclosure is not limited thereto.

The front portion FP of the cover member 20 may include a display area AA and a non-display area NA surrounding the display area AA. The non-display area NA may be formed along an edge of the display area AA. The non-display area NA may refer to a bezel area. The present disclosure is not limited to the term.

A lower portion of the non-display area NA of the display panel 100 may include a pad portion PAD or a bending portion.

The display panel 100 may include the front portion FP, the bending portion, and the pad portion PAD. The bending portion may be bent downward. The pad portion PAD may extend from the bending portion and be disposed under the front portion FP. A driver 500 for driving a pixel may be mounted on the pad portion PAD, or a flexible circuit board 600 may be connected to the pad portion PAD. The flexible circuit board 600 may be electrically connected to the pad portion PAD provided at a distal end of the display panel 100 via a film attaching process using a conductive adhesive layer, and may be located on the back surface of the display panel 100. The conductive adhesive layer may be embodied as an anisotropic conductive film (ACF). The present disclosure is not limited thereto.

In another example, the display panel 100 may extend from the front portion FP to the pad portion PAD and may be free of the bending portion. For example, the front portion FP and the pad portion PAD may be disposed in the same plane, and the flexible circuit board may be bent such that the driver and the printed circuit board are disposed under the display panel 100.

In order to reduce the non-display area NA of a lower side of the display panel 100 where the pad portion PAD or the bending portion is located, it is necessary to reduce the radius of curvature of the bending portion or the flexible circuit board.

The radius of curvature of the bending portion or the flexible circuit board may be proportional to the total thickness of the display panel 100. As the total thickness increases, the radius of curvature of the bending portion or the flexible circuit board increases, resulting in an increase in the non-display area NA. Conversely, as the total thickness thereof decreases, the non-display area NA may decrease.

Therefore, in order to reduce the non-display area NA, it is necessary to reduce the thickness of the display panel 100.

According to an aspect of the present disclosure, various manufacturing apparatuses and inspection apparatuses may be used to manufacture the display apparatus 10. In order to use each of the various manufacturing apparatuses and inspection apparatuses, the display apparatus must be mounted on and detached from the apparatuses several times. For example, a side surface of the display panel 100 before the cover member 20 is disposed may be easily damaged when a strong impact is applied to the side surface.

Moreover, the side surface thereof may be easily damaged even when the user drops the display apparatus 10 due to carelessness during use thereof. Thus, it may be necessary to reinforce the rigidity of the side surface of the display apparatus 10.

To reinforce the rigidity of the side surface of the display apparatus 10, a metal powder 316 may be disposed on a side surface of a cushion plate 300. The metal powders 316 may be disposed on the entirety of each of an upper side surface, a lower side surface, a left side surface, and a right side surface of the cushion plate 300. According to another aspect of the present disclosure, the bending portion of the display panel 100 or a bent portion of the flexible circuit board 600 may serve as cushion means at the lower side surface of the display panel 100. In this case, the metal powders 316 may not be disposed at the lower side face of the cushion plate 300.

The cushion plate 300 may include a porous member 310 and an adhesive member (not shown in FIG. 1B). The metal powders 316 may be disposed on the side face of the porous member. The porous member 310 may be a metal foam or a porous substrate.

The side surface of the cushion plate 300 or the porous member may include a side surface and an upper surface and a lower surface located in a certain area of a distal end of the cushion plate 300. A side area thereof may be an area including the side surface and a plurality of pores located in the side surface.

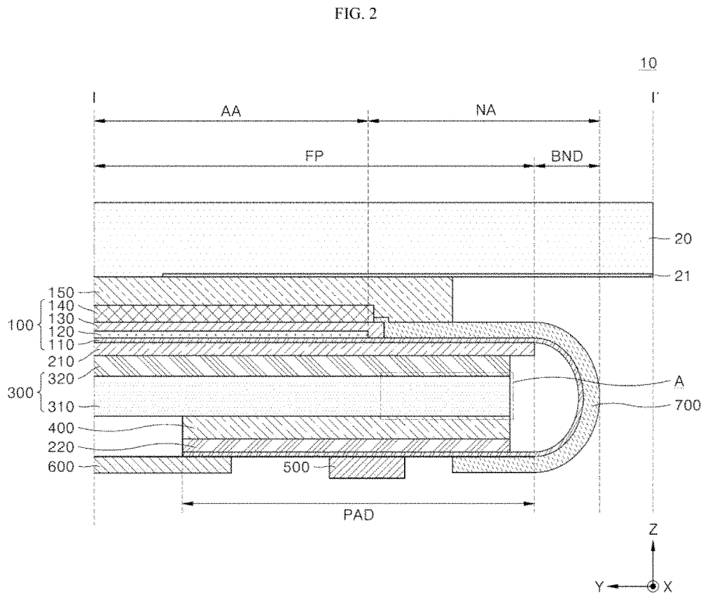

Hereinafter, the display apparatus 10 and the display panel 100 according to an aspect of the present disclosure will be described in detail with reference to FIG. 2.

FIG. 2 is a cross-sectional view taken along I-I′ in FIG. 1A.

Referring to FIG. 2, the display panel 100 may be connected or coupled to the back surface of the cover member 20.

The display panel 100 may include the front portion FP, the bending portion BND, and the pad portion PAD bent from the bending portion BND so as to be positioned on a back surface of the front portion FP. A cushion plate 300 and a connection member 400 may be disposed between the front portion FP and the pad portion PAD. The connection member 400 may be disposed to fix the cushion plate 300 and the pad portion PAD to each other.

A first plate 210 may be optionally disposed on the lower surface of the front portion FP. The first plate 210 may complement the rigidity of the display substrate 110 and keep a portion of the display substrate 110 constituting the front portion FP in a flat state. Moreover, a second plate 220 may be disposed on an upper surface of the pad portion PAD, and may complement the rigidity of the pad portion PAD. For example, the second plate 220 may be optionally disposed on the upper surface of the pad portion PAD so as to complement the rigidity of the pad portion PAD.

Accordingly, the first plate 210, the cushion plate 300, the connection member 400, the second plate 220, and the pad portion PAD may be sequentially stacked under the front portion FP of the display panel 100.

A light blocking layer 21 may be formed at four sides of the cover member 20. The light blocking layer 21 may prevent various parts disposed under the cover member 20 from being viewed from the outside, and may prevent external light from being incident into the display apparatus 10.

Alternatively, the light blocking layer 21 may be formed on a back surface of an edge of the cover member 20. The light blocking layer 21 may be formed by applying black ink. The light blocking layer 21 may include a conductive material, and may have conductive properties.

The structure of the display panel 100 is not limited thereto. In another example, the display panel 100 may be composed of the front portion FP and the pad portion PAD and may be free of the bending portion BND. In the display panel 100 composed only of the front portion FP and the pad portion PAD, the flexible circuit board 600 may be bent so that the driver 500 may be disposed under the display panel 100.

A first connection member 150 may be disposed on the back surface of the cover member 20, and the first connection member 150 may fix the display panel 100 to the cover member 20.

Since the first connection member 150 may be disposed to overlap with the display area AA, the connection member 150 may be made of a transparent adhesive member. For example, the first connection member 150 may be made of or include a material such as OCA (Optical Clear Adhesive), OCR (Optical Clear Resin), or PSA (Pressure Sensitive Adhesive). The present disclosure is not limited thereto.

An optical plate 140 may be further disposed between the display panel 100 and the first connection member 150. The optical plate 140 may have a form in which one or more function layers are stacked. However, the present disclosure is not limited thereto. For example, the optical plate 140 may include an anti-reflection layer such as a polarizing film that may prevent reflection of external light and improve outdoor visibility and contrast ratio of the image displayed on the display panel 100.

Further, the optical plate 140 may further include a barrier layer to prevent penetration of moisture or oxygen. The barrier layer may be made of a material with low moisture permeability, such as a polymer material.

The display panel 100 may include the display substrate 110, a pixel array 120 disposed on the display substrate 110, and an encapsulation portion 130 disposed to cover the pixel array 120. A touch electrode may be additionally disposed on the encapsulation portion 130.

The display substrate 110 may serve as a base substrate of the display panel 100. The display substrate 110 may be embodied as a flexible display substrate 110 as the substrate is made of a flexible plastic material.

For example, the display substrate 110 may include polyimide as a flexible plastic material, or may be made of a glass material having flexibility.

The display substrate 110 is not limited thereto, and may be made of a glass material having a constant thickness and non-bendable.

The pixel array 120 may correspond to an area for displaying an image toward the front surface of the cover member 20, and may correspond to the display area AA.

Accordingly, an area of the cover member 20 corresponding to the pixel array 120 may be a display area AA, and an area thereof other than the display area AA may be a non-display area NA.

The pixel array 120 may be implemented in a form of various elements that display an image. The pixel array is not specifically limited.

The pixel array 120 may include a plurality of pixels disposed respectively in a plurality of pixel areas defined by signal lines on the display substrate 110 and displaying an image based on a signal supplied to the signal lines. The signal lines may include a gate line, a data line, and a pixel driving power line.

Each of the plurality of pixels has a driving thin-film transistor in the pixel area, an anode electrode electrically connected to the driving thin-film transistor, a light-emitting element layer formed on the anode electrode, and a cathode electrode electrically connected to the light-emitting element layer.

The driving thin-film transistor may include a gate electrode, a semiconductor layer, a source electrode, and a drain electrode. The semiconductor layer of the driving thin-film transistor may include silicon such as a-Si, poly-Si, low-temperature poly-Si, or oxide such as IGZO (Indium-Gallium-Zinc-Oxide). The present disclosure is not limited thereto.

The anode electrode may be disposed in each pixel area in a corresponding manner to an opening area defined according to a pattern shape of the pixel and may be electrically connected to the driving thin-film transistor.

The light-emitting element layer may include, for example, an organic light-emitting element formed on the anode electrode. The light-emitting element may be implemented to emit light of the same color such as white light for each pixel or to emit light of a different color such as red, green, or blue for each pixel.

The cathode electrode may be commonly connected to the light-emitting elements of the light-emitting element layer disposed respectively in the pixel areas.

The encapsulation portion 130 may be formed on the display substrate 110 so as to cover the pixel array 120. The encapsulation portion 130 may prevent penetration of oxygen, moisture, or a foreign material into the light-emitting element layer of the pixel array 120. For example, the encapsulation portion 130 may be formed in a multi-layer structure in which organic material layers and inorganic material layers are alternately stacked with each other.

The display panel 100 may be divided into the front portion FP, the bending portion BND, and the pad portion PAD.

The front portion FP of the display panel 100 may be disposed on the side which the screen is displayed. The bending portion BND may be a portion that extends from the front portion FP and is bent in a downward direction. The pad portion PAD may be a portion extending from the bending portion BND and may be located on the back surface of the front portion FP.

A first plate 210 may be disposed under the display substrate 110. For example, the first plate 210 may be optionally disposed under the display substrate 110. When the rigidity of the cushion plate 300 disposed under the display substrate 110 is great, the first plate 210 may not be disposed. The first plate 210 may be referred to as a back plate. However, the present disclosure is not limited to the term.

Because the first plate 210 is formed to have a certain strength and thickness to supplement the rigidity of the display substrate 110, the first plate 210 may not be formed on a portion of the display panel 100 corresponding to the bending portion BND.

A second plate 220 may be disposed on the pad portion PAD of the display panel 100 bent from the bending portion BND of the display panel 100 so as to be positioned on the back surface of the front portion FP. The second plate 220 may be optionally disposed. Thus, the second plate 220 may be omitted. A component with rigidity other than the second plate 220 may be disposed. The second plate 220 may be referred to as a back plate. The present disclosure is not limited to the term.

Based on a shape before the display panel 100 is bent, the second plate 220 may be disposed below the display substrate 110 so as to be spaced apart from the first plate 210. The second plate 220 may be disposed under the pad portion PAD of the display panel 100.

Moreover, based on a shape after the display panel 100 is bent, the second plate 220 may be located above the pad portion PAD. The first plate 210 and the second plate 220 may be positioned between the front portion FP and the pad portion PAD.

The second plate 220 may be disposed under the display substrate 110 so as to complement the rigidity of the display substrate 110 such that the display substrate 110 located on the pad portion PAD may be maintained in a flat state. Thus, the connection between the pad portion PAD and the flexible circuit board 600 may be facilitated.

The cushion plate 300 may be disposed under the first plate 210. The cushion plate 300 may include a porous member 310 and an adhesive member 320. The porous member 310 may be a metal foam or a porous substrate. For example , the porous member 310 may be disposed on a lower surface of the display panel 100.

The porous member 310 may simultaneously perform a heat-dissipation function and an impact absorption function, and may be formed in a small thickness such that a total thickness and a total size of the display apparatus 10 may be reduced.

The adhesive member 320 may be stacked on an upper surface of the porous member 310 and may have a certain thickness. The porous member 310 may be positioned on a lower surface of the adhesive member 320.

The adhesive member 320 includes an adhesive component. The porous member 310 may be connected to the first plate 210 or the display panel 100 via the adhesive member 320.

The connection member 400 may be disposed between the cushion plate 300 and the second plate 220. The connection member 400 keeps a curved shape of the display panel 100. The connection member 400 may be formed to have a constant thickness in a thickness direction to maintain a constant curvature of the bending portion BND.

For example, the connection member 400 may be a double-sided tape having adhesive force that may fix the second plate 220 and the porous member 310 to each other. The present disclosure is not limited thereto. The connection member 400 may be a foam tape or a foam pad with adhesive force and may be configured to mitigate the impact.

The second plate 220 may be disposed under the connection member 400. To fix the second plate 220 to a bottom of the connection member 400, the second plate 220 may be fixed to the bottom of the pad portion PAD, and then the bending portion BND may be bent such that the second plate 220 may be attached and fixed to the lower surface of the connection member 400.

While the second plate 220 is fixed to the connection member 400, an outer portion as a upper surface of the bending portion BND is exposed to the outside, and an inner portion as a lower surface of the bending portion BND faces a side surface of each of the cushion plate 300 and the connection member 400.

A reinforcing member 700 may be disposed on the outer portion as the upper surface of the bending portion BND. The reinforcing member 700 may cover the bending portion BND and may extend to cover at least a partial area of each of the front portion FP and the pad portion PAD.

The reinforcing member 700 may include resin. For example, the reinforcing member 700 may include UV-curable resin. The present disclosure is not limited thereto. For example, the UV-curable resin may be an acrylic resin. The present disclosure is not limited thereto.

The reinforcing member 700 may be embodied as a cured product of a resin obtained by coating or forming a resin and performing a curing process thereof. When using the ultraviolet (UV)-curable resin as the resin, the resin may be cured using UV. Various materials may be used for the reinforcing member 700. The material thereof is not limited to the material described in the present disclosure.

Since the reinforcing member 700 may cover various signal lines disposed between the encapsulation portion 130 and the pad portion PAD of the display panel 100, the reinforcing member 700 may prevent moisture from penetrating into the signal line while protecting the signal line from external impact.

In the bending portion BND, some components other than the display substrate 110 and signal line may be removed to increase the flexibility of the display panel 100. The reinforcing member 700 may supplement the rigidity of the bending portion BND.

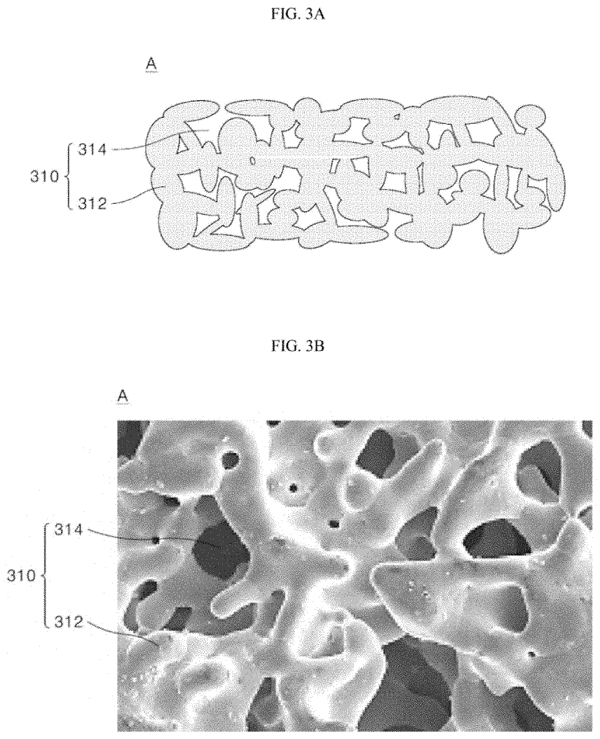

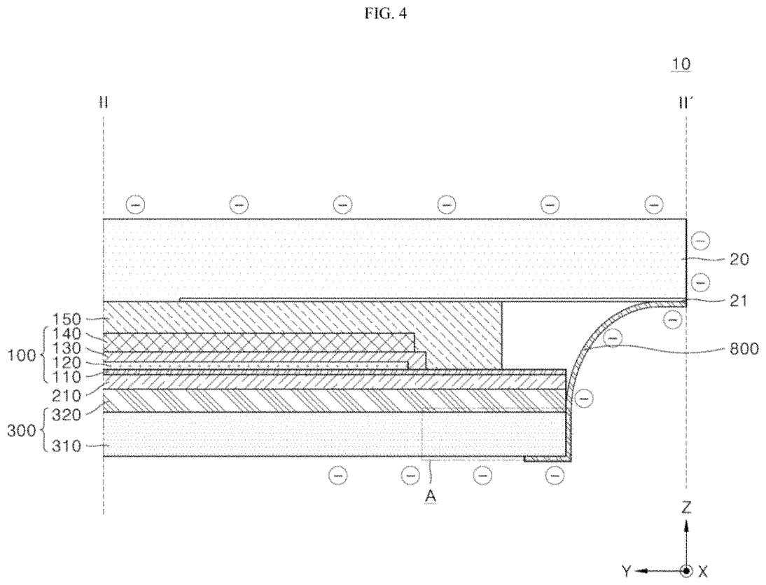

Hereinafter, the porous member 310 according to an aspect of the present disclosure will be described with reference to FIG. 3A.

FIG. 3A is an enlarged view of A area of FIG. 2, and is a cross-sectional view showing a porous member according to an aspect of the present disclosure.

FIG. 3B is a microscopic image of a portion of the porous member of FIG. 3A.

Referring back to FIG. 3A, the porous member 310 may have a porous metal structure including a conductive metal 312 and a plurality of pores 314 positioned inside the conductive metal 312.

Since the conductive metal 312 of the porous member 310 is made of metal with high thermal and electrical conductivity, the porous member 310 itself may provide an excellent heat-dissipation function and charge dispersion function. Since the porous member 310 has the form of a metal structure having a plurality of pores 314 formed therein, the porous member 310 may also provide an excellent cushion function.

Further, since the porous member 310 includes the conductive metal 312 including the plurality of pores 314 formed therein, the overall surface area of the porous member 310 can be increased, so that the porous member 310 itself may provide a heat-dissipation function.

Therefore, the porous member 310 according to an aspect of the present disclosure may have effective heat-dissipation function and cushion function at the same time without the need to configure a heat-dissipation layer for the heat-dissipation function and a cushion layer for the cushion function as separate layers. Moreover, since the porous member 310 has high electrical conductivity, there is no need to provide an additional discharge layer for dispersing the charges.

Further, since there is no additional component for heat-dissipation and/or-charge discharging functions, the display apparatus may be formed to have a smaller thickness. Therefore, the overall thickness of the display apparatus may be reduced. A width of the non-display area NA may be reduced.

A porosity of the porous member 310 having the plurality of pores 314 may be in a range of 50% to 76%, and a size of each pore may be in a range of 20 μm to 30 μm. When the porosity is lower than the above range, the porous member 310 becomes heavy, and the heat-dissipation effect is lowered. Conversely, when the porosity is higher than the above range, it is difficult to maintain a desired stiffness.

The porous member 310 may be formed by sintering a metal foam precursor. The metal foam precursor refers to a structure before proceeding with a process, such as the sintering, performed to form the porous member 310.

For example, the metal foam precursor may be formed using a slurry containing a metal powder, a dispersant, and a binder.

The metal powders may be a metal powder in which one or more metal powders among a copper powder, a nickel powder, an iron powder, a stainless steel (SUS) powder, a molybdenum powder, a silver powder, a platinum powder, a gold powder, an aluminum powder, a chromium powder, an indium powder, a tin powder, a magnesium powder, a phosphorus powder, a zinc powder, or a manganese powder are mixed, or a powder of an alloy of one or more metals, but may not be limited thereto.

The stainless steel (SUS) powder may be a metal powder in which chromium (Cr) is added to iron (Fe), and may be fine-grained iron (Fe) powder.

The copper (Cu) powder has excellent thermal conductivity, electrical conductivity, and workability, and thus may be used as a material for the porous member 310. However, due to low stiffness or elasticity, the copper powder may not be restored to its original form when an impact above a certain level is applied thereto. Therefore, the porous member 310 made of the copper (Cu) powders may be applied to the display apparatus 10 used in an environment where the impact below a certain level is applied thereto.

Moreover, when the porous member 310 is made of a composite metal (or alloy) including at least one of nickel (Ni) powder and iron (Fe) powder or stainless steel (SUS) powder, thermal conductivity, electrical conductivity, and workability thereof may be lower than those of the porous member 310 made of copper (Cu) powder, but stiffness and elasticity thereof may be increased, and thus the porous member 310 may withstand great impact. Thus, even when the impact is applied thereto, the porous member 310 may be able to restore to its original shape.

For example, when the porous member 310 is made of a composite metal (or alloy) in which nickel (Ni) powder and stainless steel (SUS) powder are mixed with each other in a ratio of 7:3 to 6:4, the porous member 310 may have a shock absorption function due to the plurality of pores 314 and may have rigidity and elasticity such that the porous member does not deform even when a strong impact is applied thereto.

The material of the porous member 310 is not limited thereto.

The dispersant may, for example, use alcohol, but may not be limited thereto.

In this case, the alcohol may use monohydric alcohol having 1 to 20 carbon atoms, such as methanol, ethanol, propanol, pentanol, octanol, 2-methoxyethanol, 2-ethoxyethanol, 2-butoxyethanol, glycerol, texanol, or terpineol, dihydric alcohol having 1 to 20 carbon atoms, such as ethylene glycol, propylene glycol, hexanediol, octanediol, or pentanediol, or polyhydric alcohol, but may not be limited thereto.

A type of the binder may not be particularly limited, and may be selected based on a type of the metal component or the dispersant used in preparing the slurry.

For example, the binder may use alkyl cellulose having an alkyl group having 1 to 8 carbon atoms, such as methyl cellulose or ethyl cellulose, polyalkylene carbonate having an alkylene unit having 1 to 8 carbon atoms, such as polypropylene carbonate or polyethylene carbonate, or a polyvinyl alcohol-based binder, such as polyvinyl alcohol or polyvinyl acetate, but may not be limited thereto.

After forming the slurry to contain the metal powder, the dispersant, and the binder as described above, the slurry may be injected into a mold having a predetermined shape or coated on a substrate to form the metal foam precursor.

The metal foam precursor thus formed may be formed into the porous member 310 through the sintering process.

In this case, conditions of the sintering process are not particularly limited as long as the sintering process is performed at a temperature and for a time at which a solvent contained in the slurry may be removed to a desired level. For example, the sintering may be performed in a temperature range from about 50° C. to 250° C. for a predetermined time. However, the disclosure may not be limited thereto.

The cushion plate 300 may be formed by placing the adhesive member 320 on a upper surface of the porous member 310 after forming the porous member 310.

Alternatively, the metal foam precursor may be formed on the adhesive member 320 and may be sintered to form the porous member 310 and the cushion plate 300. Thus, a scheme for manufacturing the cushion plate 300 is not particularly limited.

The adhesive member 320 may be in contact with the first plate 210, and may fix the cushion plate 300 to the first plate 210 or the display panel 100. For example, the adhesive member 320 may be in direct contact with the first plate 210.

The adhesive member 320 may be made of or include a material such as PSA (Pressure Sensitive Adhesive), OCA (Optical Clear Adhesive), or OCR (Optical Clear Resin). The PSA (Pressure Sensitive adhesive) may be a viscoelastic adhesive that may be adhered even under a weakly applied pressure.

For example, the adhesive member 320 may be made of one or more of an acrylic-based, silicon-based, epoxy-based, or urethane-based materials having an adhesive component. The present disclosure is not limited thereto.

The adhesive member 320 may have a predetermined thickness and be composed of one layer, or may be formed in a multi-layer structure in which an adhesive layer is formed on each of a bottom and a top of a base substrate. An embossed pattern as an unevenness structure may be formed on an upper surface of the adhesive member 320, thereby preventing occurrence of air bubbles due to the adhesive member.

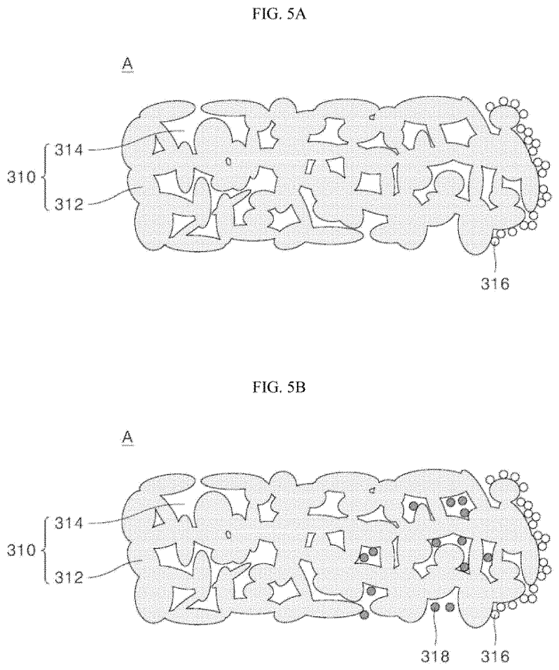

FIG. 4 is a cross-sectional view taken along of FIG. 1B. FIG. 4 shows that the porous member 310 on which the metal powders may be disposed and the back surface of the cover member 20 is connected to each other via a discharging member 800 such that the electric charge or electric field generated on the side faces of the cover member 20 and the display panel 100 moves and is discharged to the porous member 310.

Referring to FIG. 4 and FIG. 1B, the metal powders and the discharging member 800 may be applied to three sides, that is, an upper side, a left side, and a right side of the display apparatus 10 except for a lower side. Since the bending portion of the display panel 100 or a bent portion of the flexible circuit board 600 may be disposed at the lower side of the display panel 100, the discharging member 800 may not contact the porous member 310 at the lower side and thus the discharging member 800 may be omitted at the lower side.

At the three sides, that is, the upper, left, and right side of the display apparatus 10 according to an aspect of the present disclosure, the cover member 20, the display panel 100 disposed under the cover member 20, and the cushion plate 300 disposed under the display panel 100, and the discharging member 800 may be disposed.

A light blocking layer 21 may be formed at four sides of the cover member 20. The light blocking layer 21 may prevent various parts disposed under the cover member 20 from being viewed from the outside, and can prevent the external light from being incident into the display apparatus 10.

The light blocking layer 21 may be formed on a back surface of an edge of the cover member 20. The light blocking layer 21 may be formed by applying black ink. The light blocking layer 21 may include a conductive material, and may have conductive properties.

The discharging member 800 may be composed of a film or a tape including a conductive polymer compound, or may be composed of a metal sheet with high electrical conductivity. Alternatively, the discharging member 800 may be formed in a scheme of coating a conductive polymer compound on the side surface of the display apparatus 10. One side of the discharging member 800 may be connected to a back surface of the cover member 20 or the light blocking layer 21, and the other side thereof may be connected to the porous member 310.

The light blocking layer 21 and the discharging member 800 may be electrically connected to each other. Thus, the electric charge or electric field that may be generated on the surface of the cover member 20 and/or the side surface of the display panel 100 may move and be discharged to the porous member 310 through the discharging member 800.

The discharging member 800 according to an aspect of the present disclosure may reduce a phenomenon in which a distal end of the display panel 100 emits brighter light due to the electric charge or electric field generated on the surface of the cover member 20 and/or the side surface of the display panel 100 or a greenish phenomenon.

Since a plurality of pores are formed in the porous member 310 connected to the discharging member 800, a surface of the porous member 310 may be uneven and thus a surface roughness value thereof may be large.

Accordingly, even when the discharging member 800 and the porous member 310 are connected to each other, a connection resistance is high because a contact area therebetween is small. Thus, the electric charge or the electric field that may be generated on the surface of the cover member 20 and/or the side surface of the display panel 100 may not move smoothly to the porous member 310.

According to another aspect of the present disclosure, in order to form a large contact area between the discharging member 800 and the porous member 310, it is necessary to reduce the surface roughness of the porous member 310. In order to reduce the surface roughness of the porous member 310, the metal powders may be disposed on the surface of the porous member 310.

Since the side surface of the porous member 310 is connected to the discharging member 800, the metal powders may be disposed on the side surface of the porous member 310 so as to reduce the surface roughness thereof.

Further, when the metal powders may be disposed on the side surface of the porous member 310, the side surface of the porous member 310 may be reinforced, such that the display apparatus 10 may be protected from the impact applied to the side surface of the display apparatus 10.

Hereinafter, several aspects of positioning the metal powders on the side surface of the porous member 310 will be described.

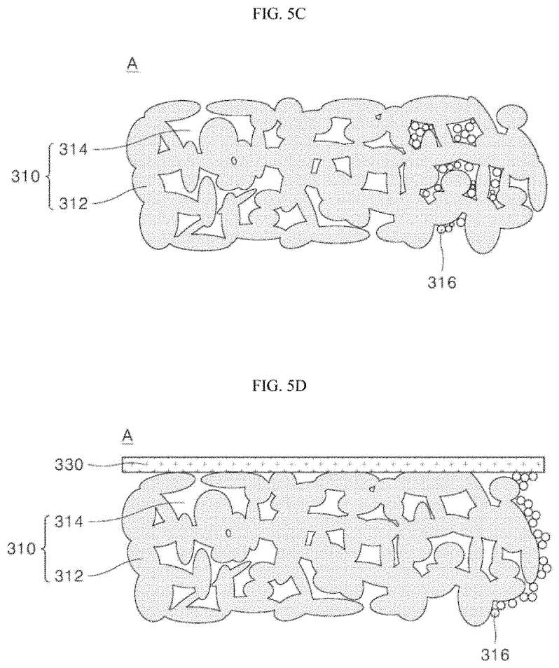

FIG. 5A to FIG. 5D are cross-sectional views showing the porous member on which the metal powders are disposed according to an aspect of the present disclosure.

Referring to FIG. 5A, metal powders 316 may be disposed or coated on the side surface of the porous member 310. The side surface of the porous member 310 may be a portion of at least one of a side surface and/or a upper surface and a lower surface of a certain area of a distal end thereof.

The metal powders 316 may include at least one of nickel (Ni) powder, iron (Fe) powder, copper (Cu) powder, aluminum (Al) powder, tungsten (W) powder, or stainless steel (SUS) powder. The metal powders 316 including the stainless steel (SUS) powder has high strength and high corrosion resistance. When the metal powders 316 including the stainless steel (SUS) powder is disposed on the side surface of the porous member 310, the display apparatus 10 may be protected from the impact applied to the side surface of the display apparatus 10.

Further, since the metal powders 316 blocks a number of pores 314 formed in the side surface of the porous member 310 by a certain amount, this may prevent moisture from penetrating from the side surface of the porous member 310 into the display panel 100. The metal powders 316 including the stainless steel (SUS) powder has high corrosion resistance, and thus may prevent rust or metal deformation caused by the moisture, and protect the porous member 310 from the moisture. Thus, waterproof performance of the porous member 310 may be improved.

Placing the metal powders 316 on the side face of the porous member 310 may allow the strength of the porous member 310 may be improved while the impact absorption function thereof is maintained. Further, since the metal powders 316 does not obstruct the flow of air in the porous member 310, the heat-dissipation performance of the porous member 310 may be maintained.

A scheme of placing the metal powders 316 on the side surface of the porous member 310 may include a spraying scheme, a pad scheme, and a plating scheme. Since various schemes may be used for disposing the metal powders 316, the present disclosure is not limited thereto.

Regarding the spraying scheme, heat may be applied to at least one of the side surface of the porous member 310 and the metal powders 316, and then the metal powders 316 may be sprayed to the porous member 310 using compressed air such that the metal powders 316 may be disposed onto the side surface of the porous member 310. Since the porous member 310 and the metal powders 316 are in contact with each other while surfaces thereof are melted due to the heat, the metal powders 316 may be easily attached to the porous member 310.

The process of the spraying scheme may be repeated several times such that the metal powders 316 may be disposed on the side surface of the porous member 310 at a desired amount.

In the pad scheme, the metal powders 316 may be disposed on a pad having elasticity, the side surface of the porous member 310 may be pressed against the pad, such that the metal powders 316 may be disposed on the side surface of the porous member 310. The process of the pad scheme may be repeated several times such that the metal powders 316 may be disposed on the side surface of the porous member 310 at a desired amount.

In the pad scheme, the process may be carried out while the heat is applied to the porous member 310 and the metal powders 316. This may facilitate the attachment of the metal powders 316 to the porous member 310.

In the plating scheme, the side surface of the porous member 310 may be immersed in a solution in which the metal powders are dissolved, and electricity may be applied such that the metal powders adhere to the surface of the porous member 310. The plating scheme is not limited thereto. Various plating schemes such as chemical plating and deposition plating may be used.

When the metal powders 316 may be disposed on a portion of the side surface of the porous member 310 where the pores 314 are formed, the surface roughness thereof may be reduced, so that the contact area between the discharging member 800 and the porous member 310 in FIG. 4 may be increased. Thus, an amount of the charge or electric field generated on the side face of member 20 or the display panel 100 which may transfer to the porous member 310 may increase.

When the metal powders 316 are made of a material with high electrical conductivity such as copper (Cu) powder, aluminum (Al) powder, or nickel (Ni) powder, the surface roughness of the porous member 310 becomes small and the electrical conductivity thereof increases, so that the movement of the electric charge or electric field may be further improved.

FIG. 5B is a cross-sectional view showing the porous member on which the metal powders are disposed according to another aspect of the present disclosure.

Referring to FIG. 5B, the metal powders 316 may be disposed on the side surface of the porous member 310. Moreover, since an organic material 318 may be disposed in the pore 314 located in the side area of the porous member 310, the display apparatus 10 may be protected from impact applied to the side surface of the display apparatus 10.

The organic material 318 may include at least one of an acrylic resin, a silicone resin, an epoxy resin, a urethane resin, an amino resin, and a phenolic resin. The material type for the organic material 318 is not limited thereto.

The organic material 318 may include a material with high elasticity. Thus, when the organic material 318 may be disposed in the pore 314 located in the side area of the porous member 310, elasticity of the porous member 310 may be improved, such that the impact applied to the side surface of the display apparatus 10 may be effectively absorbed by the porous member 310. For example, the porous member 310 may effectively absorb the pressure or impact applied from a upper surface and a lower surface of the display apparatus 10.

Therefore, the porous member 310 may have high rigidity and elasticity due to the metal powders 316 disposed on the side surface of the porous member 310 and the organic material 318 disposed in the pore 314 of the porous member 310. For example, the impact absorption function and the strength to withstand the impact of the porous member 310 may be increased.

To place or fill the organic material 318 into the pores 314 of the porous member 310, the organic material 318 may be mixed with a liquid that has low viscosity and is easily vaporized when being heated, and then, the liquid mixed with the organic material 318 may be injected into the pores 314 of the porous member 310. Then, heat may be applied to the porous member 310 to vaporize the liquid. Thus, the organic material 318 may be filled into the pores 314. The scheme for disposing the organic material 138 into the pores 314 of the porous member 310 is not limited thereto, and various schemes may be applied.

FIG. 5C is a cross-sectional view showing the porous member on which the metal powders are disposed according to still another aspect of the present disclosure.

Referring to FIG. 5C, the metal powders 316 may be disposed in the pore 314 located in the side area of the porous member 310.

Thus, the rigidity of the right side surface, left side surface, the upper side surface, and the lower side surface of the porous member 310 may be reinforced. According to an aspect of the present disclosure, when the metal powders 316 may be disposed in the pores 314 located in the side area of the porous member 310, the rigidity against the impact applied from the lower surface or the upper surface of the porous member 310 may be further improved, compared to a case when the metal powders 316 are disposed or coated on the side surface of the porous member 310.

Regarding a product in which rigidity is a more important than absorption performance against the impact applied to the side surface of the display apparatus 10, the metal powders 316 may be disposed on the side area of the porous member 310.

The metal powders 316 may include nickel (Ni) powder, SUS (stainless steel) powder, copper (Cu) powder, etc. The present disclosure is not limited thereto.

FIG. 5D is a cross-sectional view showing a porous member on which the metal powders are disposed according to still yet another aspect of the present disclosure.

Referring to FIG. 5D, a metal plate 330 may be disposed on at least one of the upper surface and the lower surface of the porous member 310. When placing the metal plate 330 on the upper surface or the lower surface of the porous member 310, the impact applied from the upper surface and/or the lower surface of the porous member 310 may be absorbed and dispersed by the metal plate 330, thereby reducing the impact applied to the porous member 310.

According to an aspect of the present disclosure, since the metal powders 316 may be disposed on the side area of the porous member 310, the rigidity of the side surface of the porous member 310 may be improved. Moreover, since the metal plate 330 may be disposed on at least one of the upper surface and the lower surface of the porous member 310, the impact applied to the upper surface and/or the lower surface of the porous member 310 may be reduced. Further, when the metal plate 330 may be disposed on the upper surface of the porous member 310, this may prevent the surface irregularities of the porous member 310 from being visually recognized by a viewer of the display apparatus 10, so that the display quality of the display apparatus may be improved.

When the metal plate 330 is made of a metal such as copper (Cu) or aluminum (Al) having high electrical conductivity, the electrical conductivity of the porous member 310 may be improved, so that a discharge function for dispersing the charges may be improved.

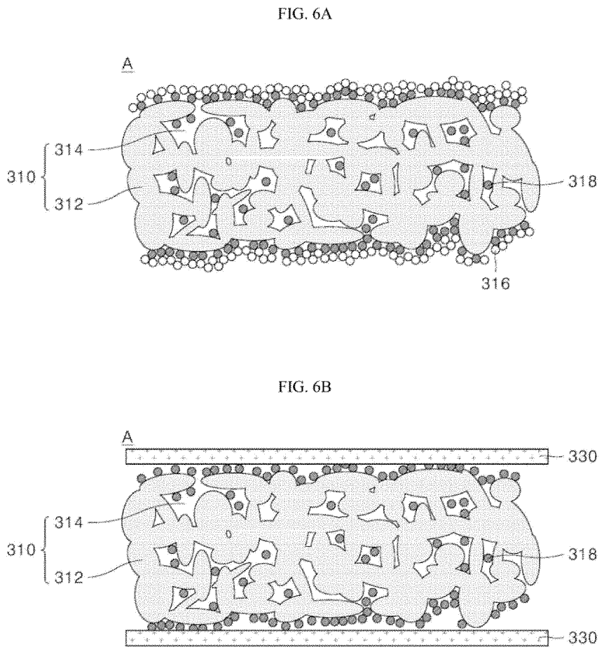

FIG. 6A is a cross-sectional view showing a porous member on which a conductive member is disposed according to an aspect of the present disclosure.

Referring to FIG. 6A, the porous member 310 includes a conductive metal 312 and a plurality of pores 314 located inside the conductive metal 312. The organic material 318 may be disposed in the plurality of pores 314, and on the upper surface, and the lower surface of the porous member 310. Moreover, the metal powders 316 as a conductive member may be disposed on the organic material 318 of the upper surface or the lower surface of the porous member 310.

When the organic material 318 is formed on an entire surface of the porous member 310, the overall strength and elasticity of the display apparatus 10 may be improved. Therefore, the porous member 310 may be applied to the display apparatus 10, which requires high overall strength.

Further, since the surface of the porous member 310 may be planarized due to the organic material 318, this may prevent the surface irregularities of the porous member 310 from being visually recognized by the viewer of the display apparatus 10.

According to an aspect of the present disclosure, disposing the metal powders 316 on the organic material 318 may prevent damage such as scratches and dents that may occur on the organic material 318 formed on the surface of the porous member 310. Further, due to the metal powders 316 disposed on the organic material 318, the rigidity and elasticity of the porous member 310 may be further improved, and the surface damage of the porous member 310 may be prevented.

In order to form the organic material 318 on an entire surface of the porous member 310, the organic material 318 may be mixed with a liquid that has low viscosity and is easily vaporized when heat is applied thereto, and then the porous member 310 may be immersed in the mixed organic material liquid, and then may be removed out thereof, and then, heat may be applied to the porous member 310 such that the organic material 318 may be formed. The scheme of forming the organic material 318 is not limited thereto.

The metal powders 316 may be disposed on the organic material 318 using the pad scheme, plating scheme, or spray scheme as described above. Since the metal powders 316 should be disposed across an entire area of the upper surface of the porous member 310, the pad scheme or plating scheme may be appropriate.

Further, the metal powders 316 may additionally fill the unevenness of the upper surface of the porous member 310 such that the flatness of the surface of the porous member 310 may be improved.

The cover member 20 and the metal powders 316 as the conductive member are connected to each other via the discharging member, so that the electric charge or electric field generated on the side surfaces of the cover member 20 and the display panel 100 may be moved and dispersed to the porous member 310.

The discharging member may be connected to the porous member 310 and the metal powders 316. The surface flatness of the porous member 310 is improved due to the metal powders 316. Thus, the contact area or a bonding area between the discharging member and the porous member 310 increases, so that an amount of the electric charge or electric field on the side surfaces of the cover member 20 and the display panel 100 transferred to the porous member 310 may be improved.

The adhesive member 320 may be disposed on the porous member 310 on which the metal powders 316 and the metal plate 330 have been stacked, and may be connected to the display panel 100.

FIG. 6B is a cross-sectional view showing a porous member on which a conductive member is disposed according to another aspect of the present disclosure.

Referring to FIG. 6B, the porous member 310 includes the conductive metal 312 and the plurality of pores 314 located inside the conductive metal 312. The organic material 318 may be disposed in the plurality of pores 314, on the upper surface, and the lower surface of the porous member 310. Moreover, on the organic material 318 of the upper surface or the lower surface of the porous member 310, a metal plate 330 as a conductive member may be disposed.

In order to form the organic material 318 on an entire surface of the porous member 310, the organic material 318 may be mixed with a liquid that has low viscosity and is easily vaporized when heat is applied thereto, and then the porous member 310 may be immersed in the mixed organic material liquid, and then may be removed out thereof, and then, heat may be applied to the porous member 310 such that the organic material 318 may be formed. The scheme of forming the organic material 318 is not limited thereto.

The porous member 310 on which the organic material 318 has been formed may have improved elasticity and rigidity.

According to an aspect of the present disclosure, disposing the metal plate 330 on the organic material 318 may prevent damage such as scratches and dents that may be caused by the organic material 318 formed on the surface of the porous member 310. Further, placing the metal plate 330 on the organic material 318 may allow the rigidity and elasticity of the porous member 310 to be further improved, and may allow the surface damage of the porous member 310 to be prevented.

Further, due to the presence of the metal plate 330, the surface unevenness of the porous member 310 is not visually recognized by the viewer, such that the display quality may be improved.

The metal plate 330 may be made of stainless steel (SUS), copper (Cu), aluminum (Al), or the like depending on the purpose of use of the metal plate. The present disclosure is not limited thereto.

The cover member 20 and the conductive member as the metal plate 330 may be connected to each other via the discharging member, so that the electric charges or electric field may be moved and dispersed.

Since the metal plate 330 has a flat surface, the discharging member may be easily connected to the upper surface of the metal plate 330. Thus, an attachment area or a contact area therebetween may be increased, such that the mobility of the electric charge or electric field may be improved.

The metal powders 316 and the metal plate 330 which act as the conductive member may be stacked and disposed on the porous member 310. For example, since the metal plate 330 may be disposed on the metal powders 316, rigidity and electrical conductivity of the porous member 310 may be further improved.

The adhesive member 320 may be disposed on the porous member 310 on which the metal powders 316 or the metal plate 330 has been stacked, and may be connected to the display panel 100.

A display apparatus according to an aspect of the present disclosure may be described as follows.

According to an aspect of the present disclosure, a display apparatus comprises a display panel to display an image; and a cover member disposed on a upper surface of the display panel and protecting the display panel from external impact; and a porous member disposed on a lower surface of the display panel, wherein metal powders are disposed on a side surface of the porous member.

In some aspects of the present disclosure, the porous member includes a conductive metal and a plurality of pores located inside the conductive metal, wherein an organic material is disposed in at least some of the plurality of pores.

In some aspects of the present disclosure, the organic material is disposed in pores located in a side area of the porous member.

In some aspects of the present disclosure, the porous member includes a conductive metal and a plurality of pores located inside the conductive metal, wherein the metal powders are disposed in the pores located in a side area of the porous member.

In some aspects of the present disclosure, the display apparatus further comprises a metal plate disposed on a upper surface of the porous member.

In some aspects of the present disclosure, the porous member is made of a composite metal including at least one of nickel (Ni), iron (Fe), or stainless steel (SUS).

In some aspects of the present disclosure, each of the metal powders includes at least one of nickel (Ni), iron (Fe), copper (Cu), aluminum (Al), or tungsten (W).

In some aspects of the present disclosure, the display apparatus further comprises a discharging member connecting the cover member and the porous member to each other.

In some embodiments of the present disclosure, the display apparatus further comprises a light blocking layer formed at four sides of the cover member, and the light blocking layer and the discharging member are electrically connected to each other.

According to an aspect of the present disclosure, a display apparatus comprises a display panel to display an image; a cover member disposed on a upper surface of the display panel and protecting the display panel from external impact; a porous member disposed on a lower surface of the display panel and including a conductive metal and a plurality of pores located inside the conductive metal; and a conductive member disposed on a upper surface or a lower surface of the porous member, wherein an organic material is disposed in the plurality of pores of the porous member.

In some aspects of the present disclosure, the conductive member includes metal powders.

In some aspects of the present disclosure, the conductive member includes a metal plate.

In some embodiments of the present disclosure, the organic material is further disposed on the upper surface or the lower surface of the porous member, and the metal plate is disposed on the organic material on the upper surface or the lower surface of the porous member.

In some aspects of the present disclosure, the conductive member includes metal powders disposed on a upper surface of the porous member; and a metal plate disposed on the metal powders.

In some aspects of the present disclosure, the display apparatus further comprises a discharging member connecting the cover member and the conductive member to each other.

According to an embodiment of the present disclosure, a display apparatus comprises a display panel to display an image; a cover member disposed on a upper surface of the display panel and protecting the display panel from external impact; and a cushion plate disposed under the display panel, wherein the cushion plate include a porous member and an adhesive member, the porous member is connected to the display panel via the adhesive member, and metal powders are disposed in pores located in a side area of the porous member.

Although the aspects of the present disclosure have been described above in more detail with reference to the accompanying drawings, the present disclosure is not necessarily limited to the aspects, and various modifications may be made within the scope that does not deviate from the technical spirit of the present disclosure. Therefore, the aspects as disclosed in the present disclosure are to illustrate the disclosure rather than limiting the technical idea of the present disclosure, and the scope of the technical idea of the present disclosure is not limited to the aspects. Therefore, it should be understood that the aspects as described above are illustrative in all respects and not restrictive. The protective scope of the present disclosure should be interpreted based on the claims, and all technical ideas within the scope equivalent thereto should be construed as being included in the scope of the present disclosure.

What is claimed is:

1. A display apparatus comprising:
a display panel configured to display an image;
a cover member disposed on an upper surface of the display panel and protecting the display panel from an external impact; and
a porous member disposed on a lower surface of the display panel,
wherein metal powders are disposed on a side surface of the porous member.

2. The display apparatus of claim 1, wherein the porous member includes a conductive metal and a plurality of pores located inside the conductive metal and an organic material disposed in at least some of the plurality of pores.

3. The display apparatus of claim 2, wherein the organic material is disposed in pores located in a side area of the porous member.

4. The display apparatus of claim 1, wherein the porous member includes a conductive metal and a plurality of pores located inside the conductive metal, and
wherein the metal powders are disposed in pores located in a side area of the porous member.

5. The display apparatus of claim 1, wherein further comprising a metal plate disposed on an upper surface of the porous member.

6. The display apparatus of claim 1, wherein the porous member is made of a composite metal including at least one of nickel (Ni), iron (Fe) and stainless steel (SUS).

7. The display apparatus of claim 1, wherein each of the metal powders includes at least one of nickel (Ni), iron (Fe), copper (Cu), aluminum (Al) and tungsten (W).

8. The display apparatus of claim 1, further comprising a discharging member connecting the cover member and the porous member.

9. A display apparatus comprising:
a display panel configured to display an image;
a cover member disposed on an upper surface of the display panel and protecting the display panel from an external impact;
a porous member disposed on a lower surface of the display panel and including a conductive metal and a plurality of pores located inside the conductive metal;
a conductive member disposed on an upper surface or a lower surface of the porous member; and
an organic material is disposed in the plurality of pores of the porous member.

10. The display apparatus of claim 9, wherein the conductive member includes metal powders.

11. The display apparatus of claim 9, wherein the conductive member includes a metal plate.

12. The display apparatus of claim 9, wherein the conductive member includes:
metal powders disposed on an upper surface of the porous member; and
a metal plate disposed on the metal powders.

13. The display apparatus of claim 9, further comprising a discharging member connecting the cover member and the conductive member.

14. A display apparatus comprising:
a display panel configured to display an image;
a cover member disposed on an upper surface of the display panel and protecting the display panel from an external impact;
a cushion plate disposed on a lower surface of the display panel and absorbing the external impact and performing a heat-dissipation function;
a discharging member connected to the cover member and the cushion plate and discharging an electric charge or an electric field transferred to the display panel to the cushion plate.

15. The display apparatus of claim 14, wherein the cushion plate comprises:
a porous member including a conductive metal and a plurality of pores located inside the conductive metal;
a conductive member disposed on an upper surface or a lower surface of the porous member; and
an organic material is disposed in the plurality of pores of the porous member.

16. The display apparatus of claim 15, wherein the conductive member includes metal powders.

17. The display apparatus of claim 15, wherein the conductive member includes a metal plate.

18. The display apparatus of claim 15, wherein the conductive member comprises:
metal powders disposed on an upper surface of the porous member; and
a metal plate disposed on the metal powders.

19. The display apparatus of claim 15, further comprising a light blocking layer disposed on a back surface of the cover member and prevent external light from being incident into the display apparatus.

20. The display apparatus of claim 15, further comprising a metal plate disposed on at least one of an upper surface and a lower surface of the porous member to absorb and disperse the external impact.
